(19) United States
(12) Patent Application Publication
(10) Pub. No.: US 2024/0327988 A1
(43) Pub. Date: Oct. 3, 2024

(54) THERMAL PROCESSING CHAMBER STATE BASED ON THERMAL SENSOR READINGS

(71) Applicant: Applied Materials, Inc., Santa Clara, CA (US)

(72) Inventors: Zhepeng Cong, San Jose, CA (US); Ala Moradian, San Jose, CA (US)

(73) Assignee: Applied Materials, Inc., Santa Clara, CA (US)

(21) Appl. No.: 18/190,970

(22) Filed: Mar. 28, 2023

(51) Int. Cl. C23C 16/46; G05D 23/19

(52) U.S. Cl. CPC C23C 16/46; G05D 23/1917

(57) ABSTRACT

A method of characterizing thermal processing chambers may include training a model using temperature rate-of-change data from existing thermal processing chambers. A supervised learning process may label the rate-of-change data based on deposition profiles on substrates. The trained model may be used to characterize another chamber to determine if the predicted performance will match the chambers used to train the model. An inert process using carrier gasses may be used to capture temperature data and derive rate-of-change data without requiring the actual deposition of an layer on the substrate. The rate-of-change data may be provided to the model, which may generate component-specific outputs that characterize how well the chamber is predicted to match either finger print condition of the chamber (match at different time) or match between different chambers.

### TECHNICAL FIELD

This disclosure generally describes techniques for assessing the health of a thermal processing chamber during the semiconductor manufacturing process. More specifically, this disclosure describes monitoring a state-of-health of a chamber based on a rate-of-change indicated by thermal sensor readings.

### BACKGROUND

Epitaxial deposition may include any type of crystal growth or deposition performing new crystalline layers in a known orientation with respect to a seed layer. Many modern semiconductor devices utilized epitaxial growth on silicon substrate wafers. For example, providing a silicon-based precursor to a deposition chamber at high temperatures may allow incremental layers of a film last to form that aligns with the crystalline lattice of the underlying seed layer. Conventional epitaxial film deposition typically includes a baking operation that may occur at greater than or about 700° C. or more. Epitaxial growth is being extended to different device structures, and may be used for selective deposition or growth on specific surfaces. At the same time, epitaxial film thicknesses are reducing for newer structures.

### SUMMARY

In some embodiments, a method of characterizing thermal processing chambers may include causing a thermal processing chamber to execute a process, wherein the process causes a temperature in the thermal processing chamber to vary during the process, causing temperature measurements to be recorded by one or more temperature sensors in the thermal processing chamber during the process, and/or deriving temperature rate-of-change data from the temperature measurements. The method may also include providing the temperature rate-of-change data to a model. The model may be configured to receive the temperature rate-of-change data as an input and provide an output that predicts how well a result of a thermal deposition process executed in the thermal processing chamber will match a target result. The method may additionally include receiving the output from the model that predicts how well the result of the thermal deposition process will match a target result, and characterizing the thermal processing chamber based on the output from the model.

In some embodiments, a system may include one or more processors and one or more memory devices storing instructions that, when executed by the one or more processors, cause the one or more processors to perform operations that may include causing a thermal processing chamber to execute a process, wherein the process causes a temperature in the thermal processing chamber to vary during the process, causing temperature measurements to be recorded by one or more temperature sensors in the thermal processing chamber during the process, and/or deriving temperature rate-of-change data from the temperature measurements. The operations may also include providing the temperature rate-of-change data to a model. The model may be configured to receive the temperature rate-of-change data as an input and provide an output that predicts how well a result of a thermal deposition process executed in the thermal processing chamber will match a target result. The operations may additionally include receiving the output from the model that predicts how well the result of the thermal deposition process will match a target result, and characterizing the thermal processing chamber based on the output from the model.

In some embodiments, one or more non-transitory computer-readable media may store instructions that, when executed by one or more processors, cause the one or more processors to perform operations that may include causing a thermal processing chamber to execute a process, wherein the process causes a temperature in the thermal processing chamber to vary during the process, causing temperature measurements to be recorded by one or more temperature sensors in the thermal processing chamber during the process, and/or deriving temperature rate-of-change data from the temperature measurements. The operations may also include providing the temperature rate-of-change data to a model. The model may be configured to receive the temperature rate-of-change data as an input and provide an output that predicts how well a result of a thermal deposition process executed in the thermal processing chamber will match a target result. The operations may additionally include receiving the output from the model that predicts how well the result of the thermal deposition process will match a target result, and characterizing the thermal processing chamber based on the output from the model.

In any embodiments, any and all of the following features may be implemented in any combination and without limitation. Before providing the temperature rate-of-change data to the model, the model may be trained by receiving training temperature rate-of-change data from a plurality of executions of the process executed by one or more thermal processing chambers, receiving training results of the thermal deposition process measured from substrates on which the thermal deposition process was executed by the one or more thermal processing chambers, generating training data based on the training temperature rate-of-change data that is labeled using the training results of the thermal deposition process, and/or executing a supervised learning algorithm to train the model using the training data. The one or more thermal processing chambers and the thermal processing chamber may be the same chamber, and characterizing the thermal processing chamber may include characterizing whether a current performance of the thermal processing chamber matches previous performances of the thermal processing chamber. The training temperature rate-of-change data and the training results may be received prior to a preventive maintenance of the thermal processing chamber where at least a portion of the thermal processing chamber may be disassembled, at least one component of the thermal processing chamber may be replaced, and/or the thermal processing chamber may be reassembled; and the thermal processing chamber may be characterized based on the output from the model after the preventive maintenance is completed. The process may include depositing an epitaxial layer on a substrate. The process may include causing a temperature to vary in the thermal processing chamber without active precursors flowing into the thermal processing chamber such that the temperature varies in the thermal processing chamber without depositing a layer on a substrate. The process may include an inert gas flowing into the thermal processing chamber in place of the active precursors. The process may include a plurality of process steps, where the plurality of process steps may include a plurality of temperature setpoints such that a temperature in the thermal processing chamber may move between the plurality of temperature setpoints during the process. The temperature rate-of-change data may include an approximate slope of temperature transitions between the plurality of temperature setpoints. The temperature measurements may include a time series of temperature readings from the one or more temperature sensors, and the temperature rate-of-change data may include a calculated first derivative of the time series of temperature readings. The thermal processing chamber may include a quartz dome above a susceptor, and a temperature sensor in the one or more temperature sensors may be configured to measure a temperature of the quartz dome. The thermal processing chamber may include a susceptor, a first temperature sensor in the one or more temperature sensors may be configured to measure a temperature underneath the susceptor, and a second temperature sensor in the one or more temperature sensors may be configured to measure a temperature of a substrate on top of the susceptor. The thermal processing chamber may include a liner, and a first temperature sensor in the one or more temperature sensors may be configured to measure a temperature of the liner. The model may be trained to model a thermal response of the thermal processing chamber when heat energy is added to the thermal processing chamber. The thermal response of the thermal processing chamber may account for a thermal mass of the thermal processing chamber. The output from the model may include one or more scalar values that may correspond to the one or more temperature sensors and that indicate a confidence level of how well the result of the thermal deposition process will match the target result for each of the one or more temperature sensors. Characterizing the thermal processing chamber based on the output from the model may include characterizing the thermal processing chamber as not matching one or more thermal processing chambers used to train the model, and identifying a component of the thermal processing chamber as a cause for the thermal processing chamber not matching the one or more chambers. A tolerance may be provided to the model that indicates an allowed deviation from the target result.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a schematic side cross-sectional view of a processing chamber, according to some embodiments.

FIG. 2 illustrates a flowchart of a method for training a machine-learning model to characterize a processing chamber, according to some embodiments.

FIG. 3 illustrates a block diagram of how temperature rate-of-change data may be generated from the temperature sensors, according to some embodiments.

FIG. 4 illustrates a graph of time series data measured during a process executed by an epitaxial chamber, according to some embodiments.

FIG. 5 illustrates a flow diagram to generate labels for the training temperature rate-of-change data, according to some embodiments.

FIG. 6 illustrates a flow diagram for training a model to predict epitaxial chamber performance, according to some embodiments.

FIG. 7 illustrates a flowchart of a method for characterizing epitaxial chambers, according to some embodiments.

FIG. 8 illustrates a flow diagram of using a trained model to predict the performance of a new epitaxial chamber, according to some embodiments.

FIG. 9 illustrates an alternate scenario where an existing epitaxial chamber undergoes a periodic test or preventive maintenance, according to some embodiments.

FIG. 10 illustrates an exemplary computer system, in which various embodiments may be implemented.

### DETAILED DESCRIPTION

Thermal Chemical Vapor Deposition (CVD) is one of the highest-temperature processes in semiconductor manufacturing. During the deposition process, precursor gases may flow into a processing chamber at temperatures ranging between about 400° C. and about 1100° C. during deposition and chamber cleaning processes. Temperature setpoints may change throughout the procedure according to the processing recipe, and the temperature within the chamber will ramp up/down between different setpoints based on the thermal characteristics of the chamber. The rate and quality of the epitaxial deposition may be dependent not only on the absolute temperature, but also the consistent thermal behavior of the processing chamber. Broadly, the thermal behavior of the processing chamber may represent the exact temperature distribution in the chamber at different power input levels and temperature setpoints. For example, the thermal behavior may be based on a total power provided to the processing chamber, along with the distribution of the different heat sources within the chamber. In addition to the instantaneous temperature readings, the thermal history, including the temperature rate-of-change data, may also affect the chamber health. As noted below, the thermal response may drift as the chamber ages and films build up on the interior of the chamber. This may cause chamber components to absorb different amounts of energy, and thereby require different amounts of input energy to reach the temperature setpoints.

At a more detailed level, the thermal behavior of the processing chamber may depend not only on the power input to the processing chamber. Additionally, the thermal behavior may more accurately be characterized by considering the total input flux of heat energy, the distribution of this energy, how this energy is absorbed by components in the chamber, work done by the heat in the chamber, and an outflowing flux of heat from the chamber. For example, certain components in the processing chamber may absorb heat that is emitted into the chamber by the chamber heat sources. A susceptor, a dome, various liners, and other components may absorb an amount of heat that is provided to the chamber during a deposition process based on their thermal mass. This need not be problematic so long as the heat absorbed by these components is consistent between processes and between different processing chambers.

However, a technical problem exists in epitaxial deposition technology. Specifically, the gases and heat provided to the processing chamber during epitaxial deposition may cause coatings or films to develop on surfaces of components that are exposed on the interior of the processing chamber during the deposition process. For example, while an intended epitaxial film is formed on a substrate, unwanted films may also form on exposed interior surfaces of the processing chamber at the same time. These coatings that form on the interior surfaces of the processing chamber may affect the optical properties of these components, which in turn may affect how heat is absorbed by these components during the deposition process. If these internal surfaces are not cleaned between each deposition process, the amount of heat energy absorbed by these surfaces will change as compared to an initial state of the processing chamber. Additionally, the SiC surface may change as a result of etch processes, such as an HCl etch. Other chamber components may also age over time—such as the heat lamps—that affect the energy and the energy distribution inside the chamber.

Changing the way that heat is absorbed by the interior of the processing chamber will affect the overall thermal behavior of the deposition process. Since the deposition process is heavily influenced by temperature transitions within the processing chamber, which is affected by the thermal history effect and chamber condition drift between preventive maintenance sessions, these changes may lead to mismatched results as substrates that are processed in the same processing chamber over time. These changes may also lead to mismatched results for substrates that are processed in different processing chambers that would otherwise be expected to generate the same results.

The embodiments described herein solve these and other technical problems by monitoring changes in the thermal behavior of the chamber to detect deviations from an initial state. The processing chamber may include temperature sensors that are distributed throughout the chamber and configured to measure temperatures for specific components in the processing chamber. As temperatures transition between setpoints in a deposition process, temperature rate-of-change data may be recorded for each of the temperature sensors. This temperature rate-of-change data may be used to train a model that may be used to predict whether the processing chamber will generate an ideal or expected on-wafer deposition result based on the temperature rate-of-change data. This model may be used to identify differences between processing chambers in terms of on-wafer deposition performance. The model may also be used to identify a drift or change in behavior over time of a single processing chamber as the processing chamber ages or undergoes preventive maintenance operations. Some embodiments may associate specific temperature sensors with corresponding chamber components, which may enable the model to identify a specific component causing the mismatch.

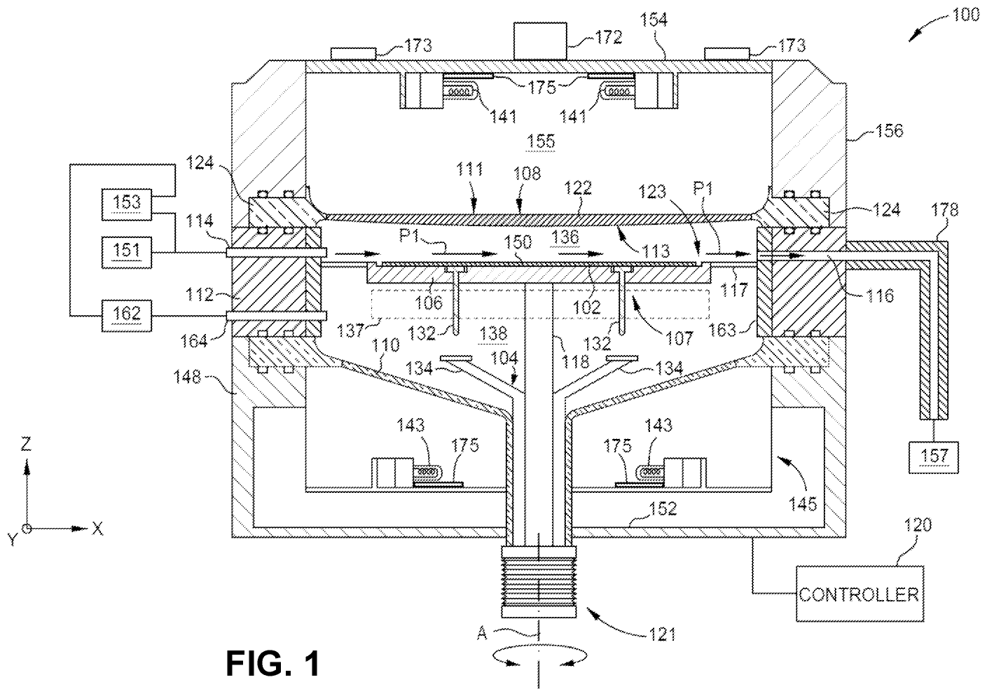

FIG. 1 illustrates a schematic side cross-sectional view of a thermal processing chamber 100, according to some embodiments. The processing chamber 100 may represent a deposition chamber. In some embodiments, the processing chamber 100 may include an epitaxial deposition chamber. The processing chamber 100 may be utilized to grow an epitaxial film on a substrate 102. The processing chamber 100 may create a flow of precursors across a top surface 150 of the substrate 102. Throughout this disclosure, and epitaxial deposition chamber may be used as a specific example of a thermal processing chamber. However, the embodiments described herein may be equally applicable to any thermal deposition chamber. Therefore, any specific reference to an epitaxial deposition chamber may be considered to also refer more generally to any thermal processing chamber.

The processing chamber 100 may include an upper body 156, a lower body 148 disposed below the upper body 156, and a flow module 112 disposed between the upper body 156 and the lower body 148. The upper body 156, the flow module 112, and the lower body 148 may form a chamber body. Disposed within the chamber body may be a substrate support 106, an upper window 108, a lower window 110 (such as a lower dome), a plurality of upper heat sources 141, and/or a plurality of lower heat sources 143. As shown, a controller 120 may be in communication with the processing chamber 100 and may be used to control processes and operations, such as the operations of the methods described herein. The controller 120 and the processing chamber 100 may be part of a larger substrate processing system or tool platform.

The processing chamber 100 may also include a plurality of upper heat sources 141 that heat a top portion of the processing chamber 100, and a plurality of lower heat sources 143 that heat a bottom portion of the processing chamber 100. The plurality of upper heat sources 141 may be disposed between the upper window 108 and a lid 154. The plurality of upper heat sources 141 may form a portion of the upper heating module 155. The plurality of lower heat sources 143 may be disposed between the lower window 110 and a chamber floor 152. The plurality of lower heat sources 143 form a portion of a lower heating module 145. In the implementation shown in FIG. 1, the heat sources 141, 143 may be heat lamps. Other heat sources may also be used without restriction, such as resistive heaters, light emitting diodes (LEDs), and/or lasers. The heat sources 141, 143 may be coupled with reflectors 175. The reflectors 175 may be configured to redirect heat energy from the heat sources 141, 143 towards the processing volume 136.

The upper window 108 may be an upper dome and is formed at least partially of an energy transmissive material, such as quartz. Therefore, the upper window 108 may also be referred to as a dome or a quartz dome. The lower window 110 is a lower dome and is formed at least partially of an energy transmissive material, such as quartz. The lower window 110 may also be referred to simply as a dome or quartz dome. The upper window 108 may include a first face 111 that is concave or flat (in the implementation shown in FIG. 1, the first face 111 is flat). The upper window 108 include a second face 113 that is convex. The second face 113 may face the substrate support 106. The upper window 108 may include an inner section 122 and/or an outer section 124. The first face 111 and the second face 113 may form at least part of the inner section 122. The inner section 122 may be transparent, and the outer section 124 may be opaque. The outer section 124 may be received at least partially in one or more sidewalls (such as in the flow module 112) of the processing chamber 100.

A process volume 136 and a purge volume 138 may be positioned between the upper window 108 and the lower window 110. The process volume 136 and the purge volume 138 may be part of an internal volume defined at least partially by the upper window 108, the lower window 110, and the one or more liners 163. The upper window 108 may at least partially define the process volume 136.

The internal volume may include the substrate support 106 disposed therein. The substrate support 106 may be disposed between the upper window 108 and the lower window 110. The substrate support 106 may include a support face 123 that supports the substrate 102. The substrate support 106 may also be referred to as a susceptor, platen, or platform. The substrate support 106 may include a top surface on which the substrate 102 is disposed. The substrate support 106 may also be attached to a shaft 118. The shaft 118 may be connected to a motion assembly 121. The motion assembly 121 may include one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 may be sized to accommodate a lift pin 132 for lifting of the substrate 102 from the substrate support 106 either before or after a deposition process is performed. The lift pins 132 may rest on lift pin stops 134 when the substrate support 106 is lowered from a process position to a transfer position. The lift pin stops 134 may be coupled to a second shaft 104. Substrates (such as the substrate 102) may be transferred into and/or out of the internal volume of the processing chamber 100 through a transfer door 137 (such as a slit valve). When the transfer door 137 is open, a transfer apparatus (with a substrate supported thereon) may extend into the internal volume through the transfer door 137 such that the lift pins 132 can lift the substrate from the transfer apparatus and land the substrate on the substrate support 106 for processing. After processing, the lift pins 132 may lift the substrate from the substrate support 106 and land the substrate on a transfer apparatus, and the transfer apparatus may be retracted through the open transfer door 137 to remove the substrate from the processing chamber 100.

The flow module 112 may include a plurality of gas inlets 114, a plurality of purge gas inlets 164, and one or more gas exhaust outlets 116. The plurality of gas inlets 114 and the plurality of purge gas inlets 164 may be disposed on the opposite side of the flow module 112 from the one or more gas exhaust outlets 116. One or more flow guides 117 may be disposed below the plurality of gas inlets 114 and/or the one or more gas exhaust outlets 116. The one or more flow guides may include, for example, one or more pre-heat rings. The one or more flow guides 117 may be disposed above the purge gas inlets 164. One or more liners 163 may be disposed on an inner surface of the flow module 112 and may protect the flow module 112 from reactive gases used during deposition operations and/or cleaning operations. The gas inlet(s) 114 and the purge gas inlet(s) 164 may each be positioned to flow a gas parallel to the top surface 150 of a substrate 102 disposed within the process volume 136. The gas inlet(s) 114 may be fluidly connected to one or more process gas sources 151 and one or more cleaning gas sources 153. The purge gas inlet(s) 164 may be fluidly connected to one or more purge gas sources 162 and/or the one or more cleaning gas sources 153. The one or more gas exhaust outlets 116 may be fluidly connected to an exhaust pump 157. One or more process gases supplied using the one or more process gas sources 151 may include one or more reactive gases (such as one or more of silicon (Si), phosphorus (P), and/or germanium (Ge)) and/or one or more carrier gases (such as one or more of nitrogen (N2) and/or hydrogen (H2)). One or more purge gases supplied using the one or more purge gas sources 162 may include one or more inert gases (such as one or more of argon (Ar), helium (He), hydrogen (H2), and/or nitrogen (N2)). One or more cleaning gases supplied using the one or more cleaning gas sources 153 may include one or more of hydrogen (H) and/or chlorine (Cl). In some embodiments, the one or more process gases may include silicon phosphide (SiP) and/or phospine (PH3), and the one or more cleaning gases may include hydrochloric acid (HCl).

The one or more gas exhaust outlets 116 may be further connected to or include an exhaust system 178. The exhaust system 178 may fluidly connect the one or more gas exhaust outlets 116 and the exhaust pump 157. The exhaust system 178 may assist in the controlled deposition of a layer on the substrate 102. The exhaust system 178 may be disposed on an opposite side of the processing chamber 100 relative to the flow module 112.

The controller 120 may include a central processing unit (CPU), a memory containing instructions, and support circuits for the CPU. For example, the controller 120 may include one or more processors. The one or more processors may be distributed between a local controller for the processing chamber 100, a tool server on a tool or platform that operates multiple processing chambers of different types, and/or at a cloud-based or facility-based server over a network or wireless connection. One or more non-transitory computer-readable media may store instructions that cause the one or more processors of the controller 120 to execute operations described herein. Collectively, the computer-readable media and the one or more processors may make up the controller 120, along with other components, which need not be limited to a single computer system. Instead, the controller 120 may be distributed between number of different computer systems in different locations. In some embodiments, the controller 120 may be communicatively coupled to dedicated controllers, and the controller 120 functions as a central controller. Alternatively, any of the operations performed or described herein may be distributed between the controller 120 and other computing systems. For example, the processing operations, model training, and/or storage of the model may be performed by the controller 120, by another non-premises competing system, by a cloud-based computing system, or by any combination of these or other systems. Some of these processing operations may also be distributed to individual sensors or control circuits in the chamber.

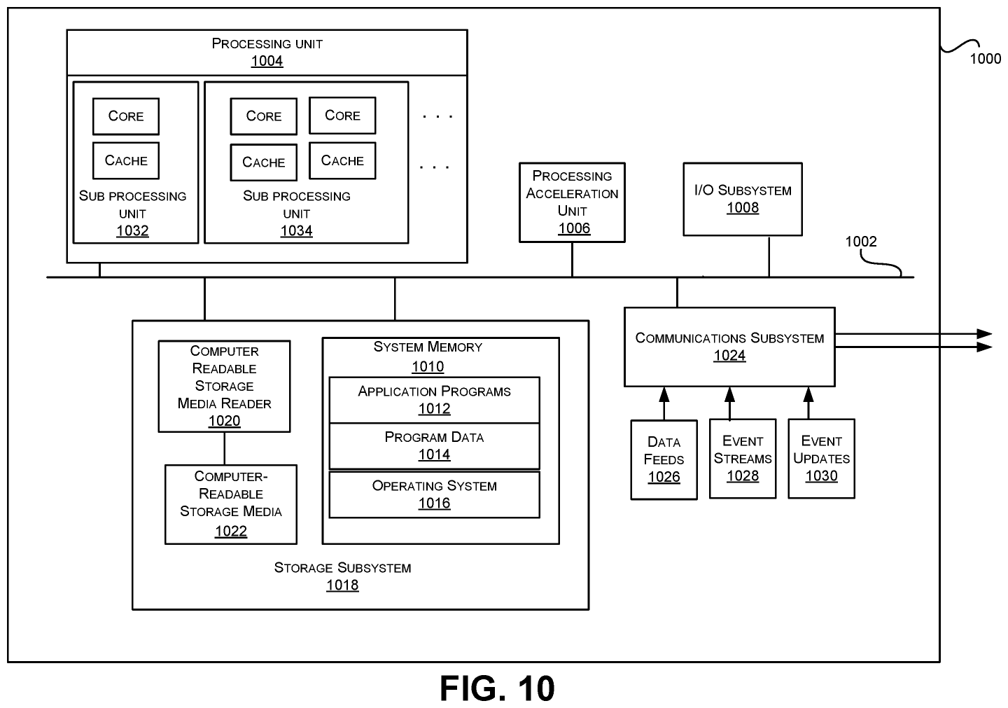

An example of a computer system that may be used to implement the least a portion of the controller 120 is described in detail below in FIG. 10. Operational parameters (a pressure for process gas, a flow rate for process gas, and/or a rotational position of a process kit) and operations may be stored in the computer-readable media as a software routine that is executed or invoked to turn the controller 120 into a specific purpose controller to control the operations of the various chambers/modules described herein. The controller 120 is configured to conduct any of the operations described herein. The various operations described herein may be conducted automatically using the controller 120, or may be conducted automatically or manually with certain operations conducted by a user.

The controller 120 may control various items directly, or via other computers and/or controllers. For example, instructions executed by the controller 120 may cause the processing chamber 100 to execute operations in a recipe, such as flowing gases, raising temperatures, receiving a substrate, and so forth. The controller 120 may be configured to control a rotational position, heating, and gas flows through the processing chamber 100 by providing an output to controls for the heat sources 141, 143, the gas flow, and the motion assembly 121. The controls may include controls for the upper heat sources 141, the lower heat sources 143, the process gas source 151, the purge gas source 162, the motion assembly 121, and the exhaust pump 157.

The controller 120 may be configured to adjust the output to the controls based off of sensor readings, a system model, and stored readings and calculations. The controller 120 may include embedded software and a compensation algorithm(s) to calibrate measurements. The controller 120 may include one or more machine learning algorithms and/or artificial intelligence algorithms that estimate optimized parameters for the deposition operations, the purge operations, and/or the cleaning operations. The one or more machine learning algorithms and/or artificial intelligence algorithms may use, for example, a regression model (such as a linear regression model) or a clustering technique to estimate optimized parameters. The algorithm can be unsupervised or supervised.

The lid 154 may include a plurality of temperature sensors disposed therein or thereon for measuring the temperature within the processing chamber 100. For example, a central temperature sensor 172 may be disposed on the lid 154 and configured to measure a temperature at or near a center portion of the processing chamber 100. More specifically, the central temperature sensor 172 may be configured to measure a temperature of the upper window 108 or quartz dome. The central temperature sensor 172 may also be configured to measure a temperature of the top surface 150 of the substrate 102 and/or the substrate support 106. One or more temperature sensors 173 may also be distributed around a periphery of the processing chamber 100. These temperature sensors 173 may be configured to measure specific locations around the periphery of the processing chamber 100. For example, these temperature sensors 173 may be pointed towards periphery portions of the upper window 108, towards internal components such as the one or more liners 163, a periphery of the substrate support 106 or susceptor, and so forth. Although not shown explicitly in FIG. 1, the processing chamber 100 may include other temperature sensors that are distributed throughout the processing chamber 100. For example, a temperature sensor may be disposed in the lower heating module 145 and positioned to measure a temperature at the periphery and/or center of the bottom of the substrate support 106.

More generally, the plurality of temperature sensors may be directed specifically towards individual components of the processing chamber 100. For example, the central temperature sensor 172 may be assigned specifically to measure a temperature at the center of the upper window 108 or the quartz dome. Temperature sensors may be specifically oriented and assigned to measure temperature underneath the susceptor or substrate support 106 and/or to measure a temperature of a substrate or a top of the susceptor or substrate support 106. A temperature sensor may be assigned and oriented specifically towards a liner in the processing chamber 100. These temperature sensor assignments are provided only by way of example and are not meant to be limiting. Any of the components depicted in FIG. 1 or described above may be assigned a specific temperature sensor that is configured to measure the temperature of that component. As will be described below, this allows individual temperature sensor data to be used to analyze a temperature rate-of-change change associated with a specific component. This in turn allows the controller to identify a specific component that may cause the processing chamber 100 to not perform as desired.

The temperature sensors may be implemented using any type of temperature sensor. For example, some embodiments may use pyrometers. Some embodiments may use thermocouples. Some embodiments may use resistance temperature detectors (RTDs). Some embodiments may use semiconductor-based temperature sensors. Some embodiments may use a temperature scanning system that includes a single sensor (e.g., a pyrometer), and which is configured to scan temperature measurements across the chamber along a predefined path through the upper/lower windows. More generally, the temperature sensors may be implemented with any device configured to provide an output that varies in a manner that is dependent on a temperature in the processing chamber 100.

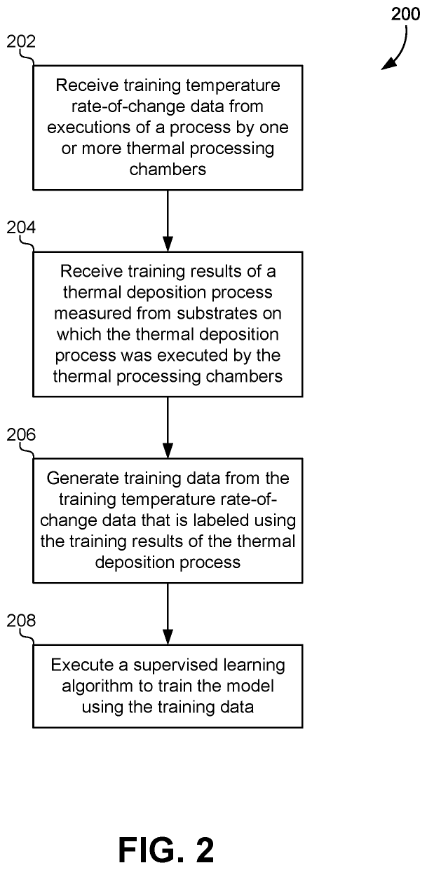

The temperature sensors may be used to sample the temperature inside the processing chamber 100 during different operations performed by the processing chamber 100. For example, the temperature sensors may be used to acquire temperature measurements that may be used to train a model. FIG. 2 illustrates a flowchart 200 of a method for training a model to characterize a processing chamber, according to some embodiments. This method may be executed by a controller, including any of the controllers and/or computer systems described herein. The processing chamber may include an epitaxial deposition chamber, or epi chamber.

The method may include receiving training temperature rate-of-change data from a plurality of executions of a process executed by one or more thermal deposition chambers (202). In some embodiments, a model may be trained for a type of epitaxial chamber, and training temperature rate-of-change data may be received from a plurality of different epitaxial chambers of this type, or from one specific chamber using one or more recipes for a specific film growth. Alternatively, some embodiments may train a model for a specific epitaxial chamber, and the training temperature rate-of-change data may be received from multiple executions of the process on the same chamber. Note the temperature data and temperature rate-o-change data are used as only one example of data that may be used to characterize the processing chamber. The embodiments described herein may also use any other characteristic of the chamber as a substitute for the temperature and temperature rate-of-change data. For example, in any embodiment, the temperature measurements may be substituted for other parameters, such as flow rate, gas concentration, and so forth. Therefore, temperature and temperature rate-of-change data are used only as an example and are not meant to be limiting. Any embodiment referring specifically to temperature may alter to use any other chamber characteristic without limitation.

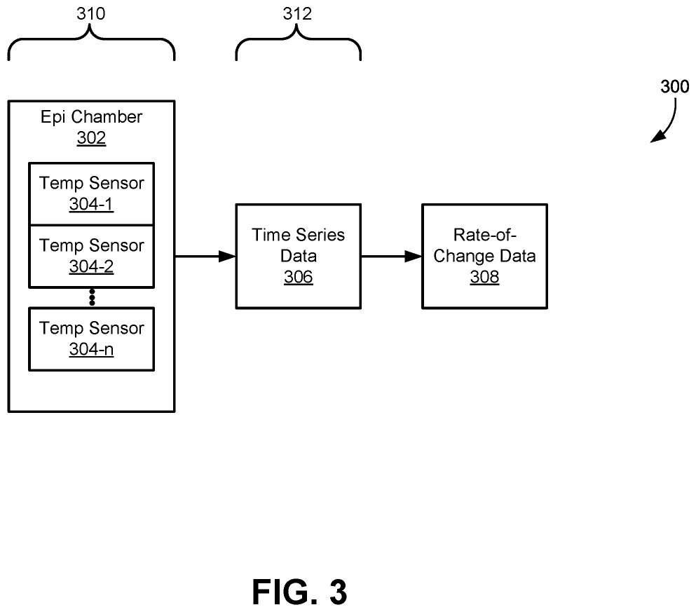

FIG. 3 illustrates a block diagram of how temperature rate-of-change data may be generated from the temperature sensors, according to some embodiments. An epitaxial chamber 302 may include a plurality of temperature sensors 304, such as those illustrated above in FIG. 1. When a process is executed by the epitaxial chamber 302, the temperature sensors 304 may record temperature measurements in real time throughout the process. A sensor sampling stage 310 may generate time series data 306 as a series of successive temperature measurements from the temperature sensors 304. The time series data 306 may then be processed by a conversion stage 312 that converts the time series data 306 to temperature rate-of-change data 308.

For example, the process executed by the epitaxial chamber 302 may include successive steps or stages. Each stage may be associated with a temperature setpoint. Transitions between these temperature setpoints in each stage may result in temperature transients as the temperature in the epitaxial chamber 302 increases or decreases between the setpoints. It has been discovered that the rate-of-change between these temperature setpoints may be more effective than absolute temperature measurements when characterizing the thermal response of the epitaxial chamber 302. Therefore, the conversion stage 312 may analyze the time series data 306 that includes the temperature transients between the setpoints and derive temperature rate-of-change data. For example, the conversion stage 312 may interpolate a slope that best fits the time series data 306 at each transition. Alternatively, the conversion stage 312 may perform a first derivative on the timeseries data 306 to calculate a slope. Therefore, the rate-of-change data 308 may include a set of first-derivative time series data, slope values, and/or any other indication of a rate-of-change that may be observed in the time series data 306.

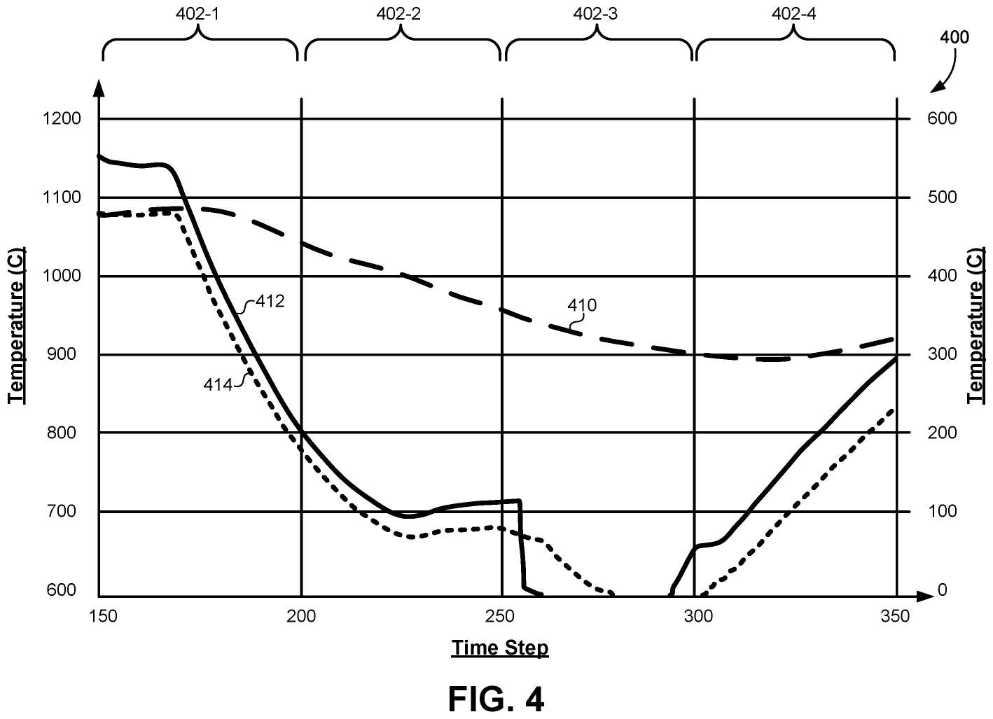

FIG. 4 illustrates a graph 400 of time series data measured during a process executed by an epitaxial chamber, according to some embodiments. The process used to generate the training temperature data may include a number of different types of processes. In some embodiments, the process may include an actual epitaxial deposition process in the epitaxial chamber, complete with an epitaxial film being deposited on a semiconductor substrate. Other embodiments may use a more efficient or accurate method of generating the training temperature data. Instead of performing an actual epitaxial deposition process, these embodiments may run a temperature cycle in the epitaxial chamber and record the temperature measurements to capture the training data. For example, temperature setpoints from a recipe of an actual epitaxial deposition process may be used. However, instead of using the active deposition precursors that are normally used in the deposition process, inert gases may be flowed into the epitaxial chamber in place of the active CVD precursors. Inert gases, such as H₂, may include any nonreactive species that does not cause a film to be deposited on the substrate or on the surfaces of the epitaxial chamber. The temperature setpoints may include custom setpoints used specifically to generate the training temperature data, or the setpoints may be used from an actual epitaxial deposition recipe. This may prevent the process that is used to generate the training temperature data without generating a film or coating on the exposed surfaces of the epitaxial chamber, while still allowing the temperature to cycle between setpoints as would occur during an actual epitaxial deposition. This also allows multiple cycles of the process to be repeatedly executed in the chamber without requiring cleaning when capturing training temperature data. As described above, the actual CVD process may generate surface coatings during use. The model and training procedure described herein may build a library of data over time to understand the performance of the chamber in response to these surface coatings and other chamber variations over time.

The graph 400 illustrates curves representing the time series measurements from the temperature sensors that may be used as the training temperature data. For example, curve 412 may represent measurements from a temperature sensor configured to measure a temperature on a top of the susceptor. Curve 414 may represent measurements from a temperature sensor configured to measure a temperature on a bottom of the susceptor. Curve 410 may represent measurements from a temperature sensor configured to measure a temperature on a window above the susceptor. Curves 412 and 414 may use the temperature scale on the left-side Y-axis, and curve 410 may use the temperature scale on the right-side Y-axis. Other temperature sensors may also record time series temperature data that are not shown explicitly in FIG. 4.

The graph 400 illustrates four different stages 402 during a process used to capture training temperature data. Each of these stages 402 may be associated with different temperature setpoints. Between these temperature setpoints, the graph 400 illustrates transient temperatures as the temperature transitions between the setpoints in each of the stages 402. For example, curve 412 may transition from a temperature setpoint of between 1100° C. and 1200° C. in stage 402-1 to a new temperature setpoint at about 700° C. in stage 402-2. The temperature transient between these two setpoints may be approximated as a linear transition. The temperature rate-of-change data may be generated by calculating a derivative of the time series data during the temperature transient, by interpolating a slope, by fitting a line to the time series data, and/or using any other method to represent the rate-of-change during the transition.

The temperature rate-of-change data may be represented as a set of estimated slope values of the transitions between each of the stages illustrated in the graph 400. These estimated slope values may be calculated for each of the temperature sensors in the epitaxial chamber. This process for collecting training temperature rate-of-change data may be repeated on the same epitaxial chamber or across a number of different epitaxial chambers. For example, one or more epitaxial chambers may be installed at a fabrication facility, and these epitaxial chambers may be used to generate the training temperature rate-of-change data. When a new epitaxial chamber is to be added to the existing epitaxial chambers at the fabrication facility, the training temperature rate-of-change data may be used to train a model to predict whether the new epitaxial chamber will match the results of the existing of the chambers.

Some embodiments may use a supervised training algorithm for training the model. The training temperature rate-of-change data collected above may be labeled by performing actual epitaxial deposition processes on substrates and using the results to label the training data. Turning back to FIG. 2, the training method of flowchart 200 may also include receiving training results of a thermal deposition process measured from substrates on which the thermal deposition process was executed by the one or more thermal deposition chambers (204).

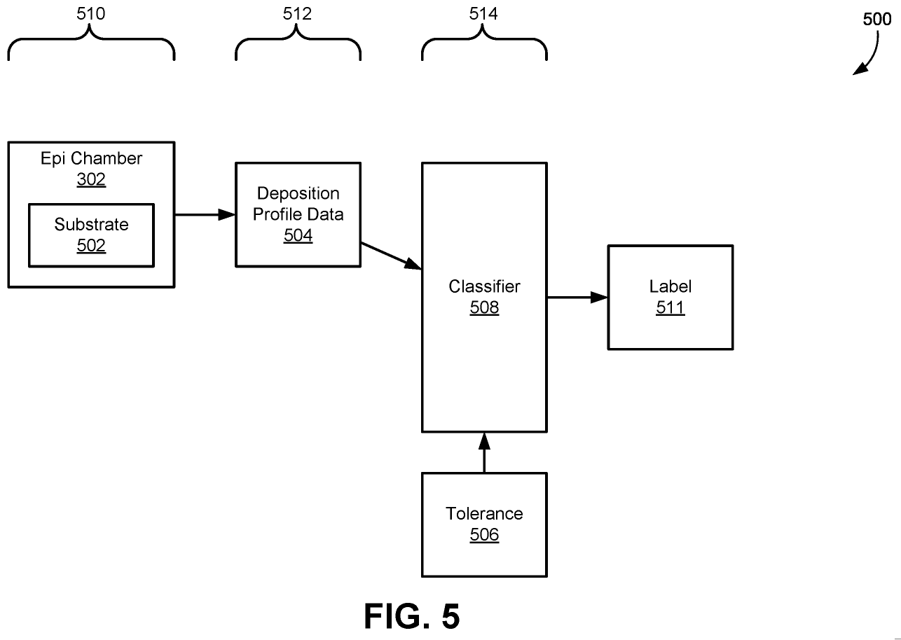

FIG. 5 illustrates a flow diagram 500 to generate labels for the training temperature rate-of-change data, according to some embodiments. After performing the process described above for generating the training rate-of-change data, the epitaxial chamber 302 may be used to perform an actual epitaxial deposition process 510 on a substrate 502. After the deposition process 510 is completed, deposition profile data 504 may be measured from the substrate 502, which may include a thickness profile of the film that is sensitive to the thermal distribution and thermal history of the chamber. A metrology process 512 or other measurement process may be performed on the substrate 502 to measure characteristics of a deposited epitaxial film. For example, the metrology process 512 may measure a film thickness at different locations on the substrate to determine film uniformity across the substrate.

The deposition profile data 504 may be provided to a classification stage 514. A classifier process 508 may be used to generate a label 511 for the deposition profile data 504. For example, the classifier process 508 may compare the thicknesses, uniformity, resistivity, strains, and/or other characteristics of the deposition profile data 504 to a target set of characteristics. A tolerance 506 may be provided to the classifier process 508. If the deposition profile data 504 is within the tolerance 506 of the target set of characteristics, the classifier process 508 may generate a label 511 indicating that the epitaxial chamber 302 is performing as expected. If the deposition profile data 504 is not within the tolerance 506 of the set of target characteristics, the classifier process 508 may generate a label 511 indicating that the epitaxial chamber is not performing as expected. In some embodiments, the label 511 may be a binary value indicating whether the epitaxial chamber 302 is performing as expected. Other embodiments may use a numeric scale or value (e.g., 0.0 to 1.0) that indicates, for example, how closely the epitaxial chamber 302 is to generating substrates with the target characteristics.

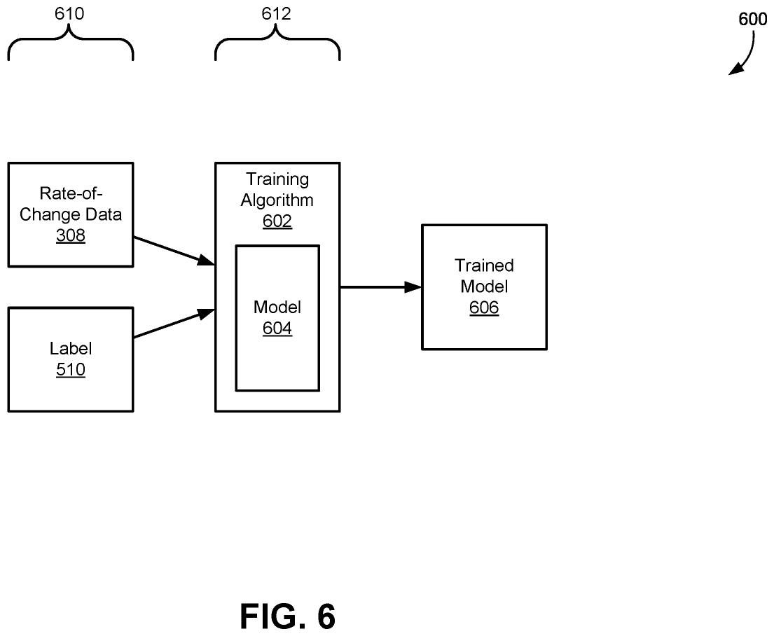

Turning back to the training method of flowchart 200 in FIG. 2, the method may also include generating training data based on the training temperature rate-of-change data that is labeled using the training results of the thermal deposition process (206). FIG. 6 illustrates a flow diagram 600 for training a model to predict epitaxial chamber performance, according to some embodiments. The training temperature rate-of-change data 308 may be labeled using the corresponding label 511 for each epitaxial chamber. For example, the epitaxial chamber may perform the temperature cycling process without active precursors using inert gases, such as H₂ as a carrier gas, to generate the training temperature rate-of-change data 308, then the epitaxial chamber may perform an actual epitaxial deposition process on a substrate, which may be measured to generate the label 511. Alternatively, the training temperature rate-of-change data 308 may be captured during an actual epitaxial deposition process on a substrate that is used to generate the label 511. The labeled training temperature rate-of-change data may be considered a training pair 610 for training the model. Although only a single training pair 610 is illustrated in FIG. 6, it should be understood that multiple training pairs may be provided to the training algorithm for the model from multiple chambers or from multiple processes from the same chamber.

The training method of flowchart 200 in FIG. 2, the method may also include executing a supervised learning algorithm to train the model using the training data (208). FIG. 6 illustrates how a training stage 612 may include performing a training algorithm 602 on a model 604. The model 604 may include a machine-learning model that is trained to model a thermal response of the epitaxial chamber when heat energy is added to the epitaxial chamber. The model 604 may account for the thermal mass of various components in the chamber, and thus the training algorithm 602 may receive the temperature measurements from component-specific temperature sensors throughout the chamber. For example, when the training algorithm 602 adjusts the weights or parameters of the model 604, these weights or parameters may be trained such that the model 604 approximates the thermal behavior of these components in absorbing or releasing heat energy based on their thermal mass. The training stage 612 may also be trained as a classification model that receives the rate-of-change data 308 and outputs a classification based on how well the input data matches the training data. For example, the model 604 may be implemented using a neural network or a convolution learn network to classify the inputs, although the model is not meant to be limited to neural networks. Any type of model may be used, including data-mode models, physics models, hybrid models, and so forth.

After the training stage 612 is complete, this process may generate a trained model 606. The trained model 606 may now be used to predict whether the performance of a new or existing epitaxial chamber will fall within a target operating range without requiring an actual deposition process and measurement of the deposition profile data on a real substrate. Additionally, the trained model 606 may be continuously retrained and/or refined over time as new training data becomes available. For example some implementations may collect temperature rate-of-change data regularly from existing epitaxial chambers. Substrates with deposited epitaxial films may also regularly undergo metrology scans that capture the deposition profile data on the substrate. This information may be combined to form new labeled training data, and the training stage 612 may be repeated to refine the trained model 606 as needed.

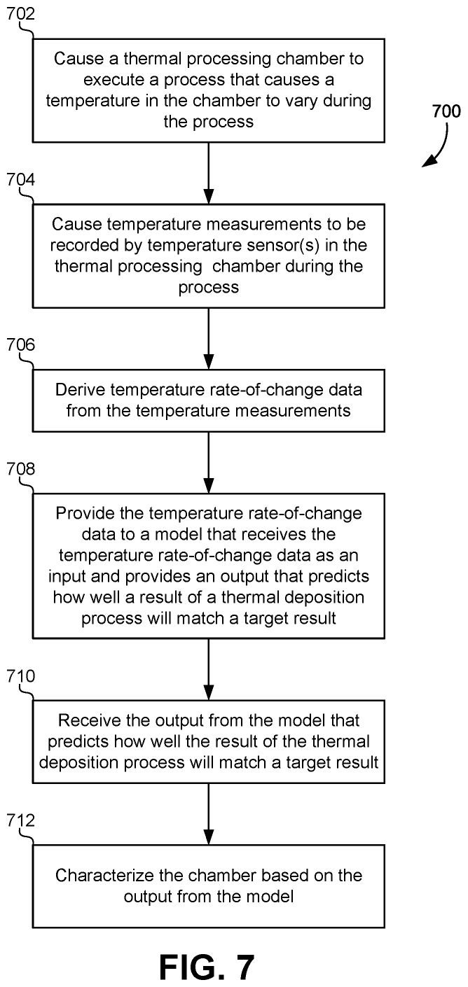

FIG. 7 illustrates a flowchart 700 of a method for characterizing epitaxial chambers, according to some embodiments. This method may be executed using the trained model 606 as described above. For example, a number of different scenarios may benefit from the use of the trained model 606 to characterize an epitaxial chamber and predict whether the performance of the epitaxial chamber will generate films within a target set of characteristics. For example, when a new epitaxial chamber is added to a manufacturing facility, matching the performance of the new epitaxial chamber with the existing performance of existing at the chambers may be of concern. The trained model 606 may be used to predict whether the performance of the new epitaxial chamber will match the performance of the existing epitaxial chambers by running the process described above to generate the temperature rate-of-change data, and by then providing this data to the trained model 606 as an input. The output of the trained model 606 may then indicate a degree or confidence level from which a match is predicted between the new chamber and the existing chambers.

The method may include causing a thermal processing chamber to execute a process that causes a temperature in the chamber to vary during the process (702). This “process” may be the same process described above in FIGS. 3-4 to generate the temperature measurements. For example, the process may be an inert process where active precursors are not provided to the epitaxial chamber and no actual epitaxial deposition takes place. Instead, the process may include a number of different temperature setpoints that allow the epitaxial chamber to transition between temperatures and exhibit the thermal reaction of the epitaxial chamber to these transitions.

The method may also include causing temperature measurements to be recorded by one or more temperature sensors in the thermal processing chamber during the process (704). As described above, temperature sensors may be associated with individual components and/or locations in the epitaxial chamber. These temperature sensors may record temperature measurements during the process as a set of time series data. The method may further include deriving temperature rate-of-change data from the temperature measurements (706). As described above, the temperature rate-of-change data may be derived using calculated derivatives, slope interpolation, line fitting, and other techniques for representing rates of change during the temperature transitions in the thermal processing chamber.

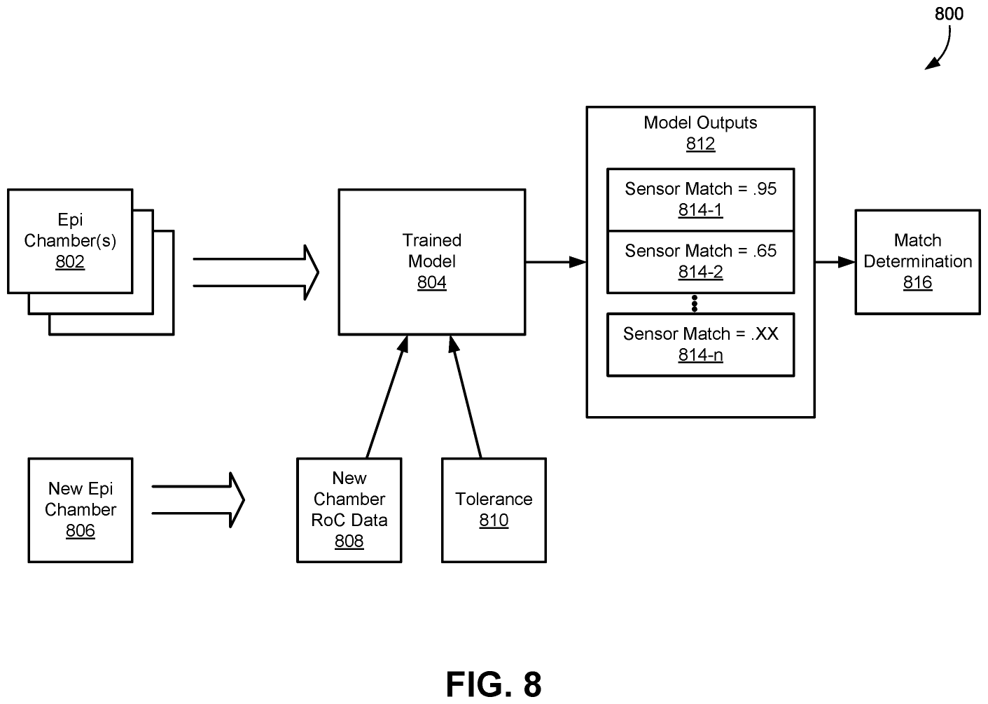

The method may additionally include providing the temperature rate-of-change data to a trained model (708). As described above, the trained model may be configured to receive the temperature rate-of-change data as an input and provide an output that predicts how well a result of an epitaxial deposition process executed in the epitaxial chamber will match a target result. The target result may include a thickness profile, resistivity, strain, crystal quality, and/or any other characteristic of the process. FIG. 8 illustrates a flow diagram 800 of using a trained model 804 to predict the performance of a new epitaxial chamber, according to some embodiments. As described in detail above, a plurality of labeled training data may be provided from one or more existing epitaxial chambers 802 in order to train or retrain the trained model 804. When a new epitaxial chamber 806 is added to the set of existing epitaxial chambers 802, the process described above may be executed on the new epitaxial chamber 806 to generate temperature rate-of-change data 808 for the new epitaxial chamber 806. The temperature rate-of-change data 808 may then be provided as an input to the trained model 804.

Some embodiments may also provide a tolerance 810 for the trained model 804. This allows for adjustment how closely the predicted performance of the new epitaxial chamber 806 needs to match the performance of the existing epitaxial chambers 802. For example, increasing the tolerance 810 may relax the classification parameters of the trained model 804 such that a predicted match is more likely. Conversely, decreasing the tolerance 810 may require the predicted performance of the new epitaxial chamber 806 to more closely match the performance of the existing epitaxial chambers 802.

The method may also include receiving the output 812 from the trained model 804 that predicts how well the result of the thermal deposition process will match a target result (710). The output 812 of the trained model 804 may include binary and/or scalar values that express a confidence level or degree with which the predictive performance of the new epitaxial chamber 806 will match the performance of the existing epitaxial chambers 802. For example, some embodiments of the trained model 804 may provide separate outputs 814 that are specific for each sensor recording the temperature measurements in the epitaxial chamber 806. This allows the outputs 812 to be used to predict an overall match of the performance of the new epitaxial chamber 806, and to also indicate how closely the thermal response of individual components will be in the new epitaxial chamber 806. For example, output 814-1 indicates a 95% likelihood of a match based on the temperature rate-of-change data from a first component (e.g., a top of the susceptor), while output 814-2 indicates only a 65% likelihood of a match based on temperature rate-of-change data from a second component e.g., a location on the quartz dome). These specific outputs indicating mismatched parameters may be used to match (e.g., adjust, replace, etc.) hardware components between chambers to improve the overall matching results.

The method may further include characterizing the thermal processing chamber based on the output from the model (712). The characterization of the new epitaxial chamber 806 may include evaluating the output 812 from the trained model 804 in order to determine an overall likelihood of a performance match between the new epitaxial chamber 806 and the existing epitaxial chambers 802. This characterization may include a binary characterization (e.g., match, no match), as well as a confidence level or degree to which the match is predicted.

In some embodiments, the characterization of the new epitaxial chamber 806 may include an identification of a specific component, such as a temperature sensor, flow controller, or any other hardware component in the new epitaxial chamber 806 as a cause for the match determination 816. In the example of FIG. 8, the match determination 816 may indicate that the new epitaxial chamber 806 is not predicted to match the performance of the epitaxial chambers 802 within the tolerance 810. The match determination 816 may further indicate that the sensor associated with output 814-2 (e.g., a temperature sensor recording temperature measurements from the quartz dome) contributes most to the mismatch. This information may be used by a user to diagnose the mismatch as a problem with the specific component. For example, the component may have been incorrectly installed such that it inadequately contacts the other interior portions of the epitaxial chamber. The quartz dome may also have a film or coating that reduces the thermal transmission of heat energy into the quartz dome. This information may be used to rectify problems with the new epitaxial chamber 806, such as reinstalling the quartz dome, replacing the quartz dome, cleaning the quartz dome, and so forth. More generally, any mismatch identified by the system may be associated with a particular component, and the model/software may therefore recommend a calibration, shift, or adjustment of that component to correct the mismatch. For example, if the mismatch is due to a drift in temperature of the dome due to a loss of transmissivity, then a shift or offset factor may be suggested to the user for re-calibration of this component/device. After any problems indicated by the match determination 816 are resolved, method of flowchart 700 may be repeated to determine whether a performance match is now predicted.

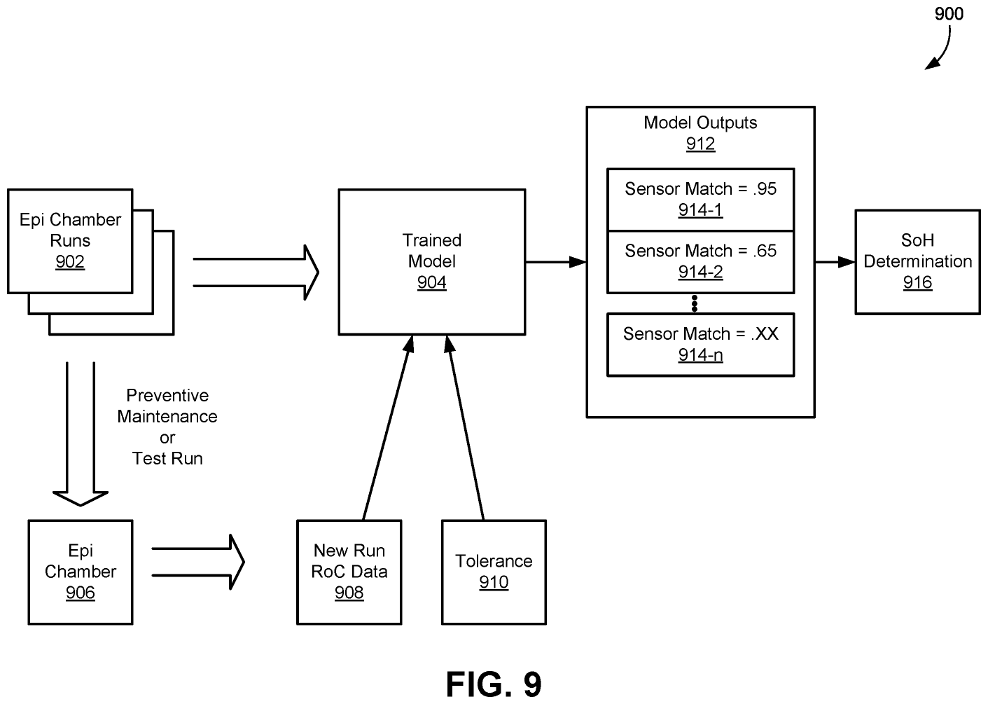

FIG. 9 illustrates an alternate scenario where an existing epitaxial chamber 906 undergoes a periodic test or preventive maintenance, according to some embodiments. As described above, training data from one or more existing at the chambers 902 may be used to generate or retrain a trained model 904. One of these epitaxial chambers 906 may undergo preventive maintenance (PM). The PM may include at least a portion of the epitaxial chamber being disassembled. The PM may also include cleaning of the epitaxial chamber and/or at least one component of the epitaxial chamber being replaced. After the epitaxial chamber 906 is reassembled following the completion of the PM, the epitaxial chamber 906 may be tested using the trained model 904 to determine whether the PM adversely affected the predicted performance of the epitaxial chamber 906.

Alternatively, the same process may be carried out as part of a test run for the epitaxial chamber 906, without necessarily requiring any PM. For example, each of the epitaxial chambers 902 may be periodically tested to identify whether the performance has drifted over time. These test results may be used to determine whether PM is needed, whether specific component replacements are needed based on the model outputs, and/or whether specific components need to be cleaned or serviced.

The epitaxial chamber 906 may be used to generate new temperature rate-of-change data 908 that is provided to the trained model 904 with an optional tolerance 910. The model may be trained prior to performing the PM or test run. The model outputs 912 may then be used to characterize the epitaxial chamber 906. For example, the characterization of the epitaxial chamber 906 may include a state-of-health determination 916, which may include an indication of drift of the performance of the epitaxial chamber 906 over time, as well as whether the epitaxial chamber 906 still falls within the tolerance 910 of the target performance. Some embodiments may also provide drift and state-of-health determinations for individual components based on the outputs 914 assigned to specific sensors as described above.

It should be appreciated that the specific steps illustrated in FIG. 2 and FIG. 7 provide particular methods of training and using a model to predict epitaxial chamber performance, according to various embodiments. Other sequences of steps may also be performed according to alternative embodiments. For example, alternative embodiments may perform the steps outlined above in a different order. Moreover, the individual steps illustrated in FIG. 2 and FIG. 7 may include multiple sub-steps that may be performed in various sequences as appropriate to the individual step. Furthermore, additional steps may be added or removed depending on the particular applications. Many variations, modifications, and alternatives also fall within the scope of this disclosure.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

FIG. 10 illustrates an exemplary computer system 1000, in which various embodiments may be implemented. The system 1000 may be used to implement any of the computer systems described above. As shown in the figure, computer system 1000 includes a processing unit 1004 that communicates with a number of peripheral subsystems via a bus subsystem 1002. These peripheral subsystems may include a processing acceleration unit 1006, an I/O subsystem 1008, a storage subsystem 1018 and a communications subsystem 1024. Storage subsystem 1018 includes tangible computer-readable storage media 1022 and a system memory 1010.

Bus subsystem 1002 provides a mechanism for letting the various components and subsystems of computer system 1000 communicate with each other as intended. Although bus subsystem 1002 is shown schematically as a single bus, alternative embodiments of the bus subsystem may utilize multiple buses. Bus subsystem 1002 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1004, which can be implemented as one or more integrated circuits (e.g., a conventional microprocessor or microcontroller), controls the operation of computer system 1000. One or more processors may be included in processing unit 1004. These processors may include single core or multicore processors. In certain embodiments, processing unit 1004 may be implemented as one or more independent processing units 1032 and/or 1034 with single or multicore processors included in each processing unit. In other embodiments, processing unit 1004 may also be implemented as a quad-core processing unit formed by integrating two dual-core processors into a single chip.

In various embodiments, processing unit 1004 can execute a variety of programs in response to program code and can maintain multiple concurrently executing programs or processes. At any given time, some or all of the program code to be executed can be resident in processor(s) 1004 and/or in storage subsystem 1018. Through suitable programming, processor(s) 1004 can provide various functionalities described above. Computer system 1000 may additionally include a processing acceleration unit 1006, which can include a digital signal processor (DSP), a special-purpose processor, and/or the like.

I/O subsystem 1008 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. Additionally, user interface input devices may include voice recognition sensing devices that enable users to interact with voice recognition systems, through voice commands. User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments, augmented reality (AR) input/output devices, virtual reality (VR) input/output devices, and/or the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1000 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1000 may comprise a storage subsystem 1018 that comprises software elements, shown as being currently located within a system memory 1010. System memory 1010 may store program instructions that are loadable and executable on processing unit 1004, as well as data generated during the execution of these programs.

Depending on the configuration and type of computer system 1000, system memory 1010 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 1004. In some implementations, system memory 1010 may include multiple different types of memory, such as static random access memory (SRAM) or dynamic random access memory (DRAM). In some implementations, a basic input/output system (BIOS), containing the basic routines that help to transfer information between elements within computer system 1000, such as during start-up, may typically be stored in the ROM. By way of example, and not limitation, system memory 1010 also illustrates application programs 1012, which may include client applications, Web browsers, mid-tier applications, relational database management systems (RDBMS), etc., program data 1014, and an operating system 1016. By way of example, operating system 1016 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 1018 may also provide a tangible computer-readable storage medium for storing the basic programming and data constructs that provide the functionality of some embodiments. Software (programs, code modules, instructions) that when executed by a processor provide the functionality described above may be stored in storage subsystem 1018. These software modules or instructions may be executed by processing unit 1004. Storage subsystem 1018 may also provide a repository for storing data used in accordance with some embodiments.

Storage subsystem 1000 may also include a computer-readable storage media reader 1020 that can further be connected to computer-readable storage media 1022. Together and, optionally, in combination with system memory 1010, computer-readable storage media 1022 may comprehensively represent remote, local, fixed, and/or removable storage devices plus storage media for temporarily and/or more permanently containing, storing, transmitting, and retrieving computer-readable information.

Computer-readable storage media 1022 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1000.

By way of example, computer-readable storage media 1022 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 1022 may include, but is not limited to, Zip® drives, flash memory cards, universal serial bus (USB) flash drives, secure digital (SD) cards, DVD disks, digital video tape, and the like. Computer-readable storage media 1022 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1000.

Communications subsystem 1024 provides an interface to other computer systems and networks. Communications subsystem 1024 serves as an interface for receiving data from and transmitting data to other systems from computer system 1000. For example, communications subsystem 1024 may enable computer system 1000 to connect to one or more devices via the Internet. In some embodiments communications subsystem 1024 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 1024 can provide wired network connectivity (e.g., Ethernet) in addition to or instead of a wireless interface.

In some embodiments, communications subsystem 1024 may also receive input communication in the form of structured and/or unstructured data feeds 1026, event streams 1028, event updates 1030, and the like on behalf of one or more users who may use computer system 1000.

By way of example, communications subsystem 1024 may be configured to receive data feeds 1026 in real-time from users of social networks and/or other communication services or web feeds such as Rich Site Summary (RSS) feeds, and/or real-time updates from one or more third party information sources.

Additionally, communications subsystem 1024 may also be configured to receive data in the form of continuous data streams, which may include event streams 1028 of real-time events and/or event updates 1030, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1024 may also be configured to output the structured and/or unstructured data feeds 1026, event streams 1028, event updates 1030, and the like to one or more databases that may be in communication with one or more streaming data source computers coupled to computer system 1000.

Computer system 1000 can be one of various types, including a handheld portable device (e.g., an iPhone® cellular phone, an iPad® computing tablet, a PDA), a wearable device, a PC, a workstation, a mainframe, a kiosk, a server rack, or any other data processing system.

Due to the ever-changing nature of computers and networks, the description of computer system 1000 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of characterizing thermal processing chambers, the method comprising:
causing a thermal processing chamber to execute a process, wherein the process causes a temperature in the thermal processing chamber to vary during the process;
causing temperature measurements to be recorded by one or more temperature sensors in the thermal processing chamber during the process;
deriving temperature rate-of-change data from the temperature measurements;
providing the temperature rate-of-change data to a model that is configured to receive the temperature rate-of-change data as an input and provide an output that predicts how well a result of a thermal deposition process executed in the thermal processing chamber will match a target result;
receiving the output from the model that predicts how well the result of the thermal deposition process will match a target result; and
characterizing the thermal processing chamber based on the output from the model.

2. The method of claim 1, further comprising, before providing the temperature rate-of-change data to the model, training the model, wherein training the model comprises:
receiving training temperature rate-of-change data from a plurality of executions of the process executed by one or more thermal processing chambers;
receiving training results of the thermal deposition process measured from substrates on which the thermal deposition process was executed by the one or more thermal processing chambers;
generating training data based on the training temperature rate-of-change data that is labeled using the training results of the thermal deposition process;
executing a supervised learning algorithm to train the model using the training data.

3. The method of claim 2, wherein:
the one or more thermal processing chambers and the thermal processing chamber are a same chamber; and
characterizing the thermal processing chamber comprises characterizing whether a current performance of the thermal processing chamber matches previous performances of the thermal processing chamber.

4. The method of claim 2, wherein:
the training temperature rate-of-change data and the training results are received prior to a preventive maintenance of the thermal processing chamber wherein at least a portion of the thermal processing chamber is disassembled, at least one component of the thermal processing chamber is replaced, and the thermal processing chamber is reassembled; and
the thermal processing chamber is characterized based on the output from the model after the preventive maintenance is completed.

5. The method of claim 1, wherein the process comprises depositing an epitaxial layer on a substrate.

6. The method of claim 1, wherein the process comprises causing a temperature to vary in the thermal processing chamber without active precursors flowing into the thermal processing chamber such that the temperature varies in the thermal processing chamber without depositing a layer on a substrate.

7. The method of claim 6, wherein the process comprises an inert gas flowing into the thermal processing chamber in place of the active precursors.

8. A system comprising:
one or more processors; and
one or more memory devices comprising instructions that, when executed by the one or more processors, cause the one or more processors to perform operations comprising:
causing an thermal processing chamber to execute a process, wherein the process causes a temperature in the thermal processing chamber to vary during the process;
causing temperature measurements to be recorded by one or more temperature sensors in the thermal processing chamber during the process;
deriving temperature rate-of-change data from the temperature measurements;
providing the temperature rate-of-change data to a model that is configured to receive the temperature rate-of-change data as an input and provide an output that predicts how well a result of an thermal processing deposition process executed in the thermal processing chamber will match a target result;
receiving the output from the model that predicts how well the result of a thermal deposition process will match a target result; and
characterizing the thermal processing chamber based on the output from the model.

9. The system of claim 8, wherein the process comprises a plurality of process steps, wherein the plurality of process steps comprises a plurality of temperature setpoints such that a temperature in the thermal processing chamber moves between the plurality of temperature setpoints during the process.

10. The system of claim 9, wherein the temperature rate-of-change data comprises an approximate slope of temperature transitions between the plurality of temperature setpoints.

11. The system of claim 8, wherein:
the temperature measurements comprise a time series of temperature readings from the one or more temperature sensors; and
the temperature rate-of-change data comprises a calculated first derivative of the time series of temperature readings.

12. The system of claim 8, wherein the thermal processing chamber comprises a quartz dome above a susceptor, and a temperature sensor in the one or more temperature sensors is configured to measure a temperature of the quartz dome.

13. The system of claim 8, wherein the thermal processing chamber comprises a susceptor, a first temperature sensor in the one or more temperature sensors is configured to measure a temperature underneath the susceptor, and a second temperature sensor in the one or more temperature sensors is configured to measure a temperature of a substrate on top of the susceptor.

14. The system of claim 8, wherein the thermal processing chamber comprises a liner, and a first temperature sensor in the one or more temperature sensors is configured to measure a temperature of the liner.

15. One or more non-transitory computer-readable media comprising instructions that, when executed by one or more processors, cause the one or more processors to perform operations comprising:
causing an thermal processing chamber to execute a process, wherein the process causes a temperature in the thermal processing chamber to vary during the process;
causing temperature measurements to be recorded by one or more temperature sensors in the thermal processing chamber during the process;
deriving temperature rate-of-change data from the temperature measurements;
providing the temperature rate-of-change data to a model that is configured to receive the temperature rate-of-change data as an input and provide an output that predicts how well a result of a thermal deposition process executed in the thermal processing chamber will match a target result;
receiving the output from the model that predicts how well the result of the thermal deposition process will match a target result; and
characterizing the thermal processing chamber based on the output from the model.

16. The one or more non-transitory computer-readable media of claim 15, wherein the model is trained to model a thermal response of the thermal processing chamber when heat energy is added to the thermal processing chamber.

17. The one or more non-transitory computer-readable media of claim 16, wherein the thermal response of the thermal processing chamber accounts for a thermal mass of the thermal processing chamber.

18. The one or more non-transitory computer-readable media of claim 15, wherein the output from the model comprises one or more scalar values that correspond to the one or more temperature sensors and that indicate a confidence level of how well the result of the thermal deposition process will match the target result for each of the one or more temperature sensors.

19. The one or more non-transitory computer-readable media of claim 15, wherein characterizing the thermal processing chamber based on the output from the model comprises:
characterizing the thermal processing chamber as not matching one or more thermal processing chambers used to train the model; and
identifying a component of the thermal processing chamber as a cause for the thermal processing chamber not matching the one or more chambers.

20. The one or more non-transitory computer-readable media of claim 15, wherein the operations further comprise providing a tolerance to the model that indicates an allowed deviation from the target result.
